(19) United States
(12) Patent Application Publication
(10) Pub. No.: US 2003/0139043 A1
(43) Pub. Date: Jul. 24, 2003

(54) Apparatus and method for monitoring a plasma etch process

(76) Inventors: Steve Marcus, Chandler, AZ (US); James Fordemwalt, Tempe, AZ (US)

Correspondence Address: PILLSBURY WINTHROP, LLP, P.O. BOX 10500, MCLEAN, VA, 22102, US

(21) Appl. No.: 10/316,204

(22) Filed: Dec. 11, 2002

Related U.S. Application Data
(60) Provisional application No. 60/338,660, filed on Dec. 11, 2001.

(51) Int. Cl. H01L 21/302; H01L 21/461

(52) U.S. Cl. 438/689

(57) ABSTRACT

An apparatus and method for monitoring a plasma etch process are disclosed which will provide for in-situ measurement of plasma wafer-charge damage with both temporal and spatial resolution. A removable test structure comprising a test wafer that may take the form of a silicon substrate with one or more test devices is provided with backside contacts. Test devices such as capacitors, MOS transistors, etc., which may be provided with antennas, are provided on the top surface of the wafer which can be electrically contacted on the backside of the substrate. The apparatus also includes a wafer chuck provided with contacts which electrically engage the back-side contacts on the substrate and communicating with the outside of the plasma chamber so that the electrical signals generated in the test devices may be measured in real-time while the plasma process is being performed on the substrate.

This non-provisional application claims benefit from U.S. Provisional Application No. 60/338,660, filed Dec. 11, 2001.

### FIELD OF THE INVENTION

The present invention relates generally to the design of semiconductor devices and more particularly to a method and system for monitoring the process of plasma etching.

### BACKGROUND

Plasma etching, utilizing an electrically generated plasma of a suitable etching gas, has commonly been employed to etch a substrate or device. There has been an ongoing concern that the electric fields involved in generating the plasma might be damaging to the devices being fabricated. Until recently, the devices being fabricated were large and robust enough that this has not been a problem. However, the newest generations of devices, e.g. semiconductor devices, are showing indications that plasma charging damage is becoming a problem. The mechanisms of plasma etching are complex. Control of the plasma parameters is a focus of significant technological development in the industry.

One of the key factors in controlling plasma parameters is the diagnosis of the plasma and wafer conditions; more specifically diagnosing the potential for charge damage to the wafer. Various conditions can be observed and used as feedback to control the system parameters, such as process gas flow rate, RF (and self-DC) bias, and wafer placement. Plasma control may be employed to control and minimize the damage to the fragile gate oxides due to the charging of MOS devices during fabrication of the devices using plasma reactors. The ability to monitor the charge on the devices in real time during plasma processing would help in developing new machines and processes, as well as for the troubleshooting of problems with operating machines.

There have been a number of schemes for monitoring the status of the plasma during the etching process. One of the most widely used has been simply to place a test wafer with appropriate test devices and device layers in the reactor, perform the desired plasma process, and then test the test devices and compare the results with either the measurements taken on the test devices before the plasma process or with expected results from other systems. Then, based on these results, the conditions in the plasma during the plasma processing are deduced. Other researchers have instrumented plasma processing chambers with a system of probes, which make contact with the top surface of a test wafer. This method has permitted the real-time, in-situ measurement of plasma parameters.

### SUMMARY OF THE INVENTION

A method and apparatus is provided which permits real-time, in-situ monitoring of plasma parameters, including, among others, the charging of the surface of the substrate being processed.

A test substrate, for example, a silicon wafer with appropriate test devices such as thin gate oxide structures, which may have metal or polysilicon antenna structures attached, capacitors, and any other test devices, is provided. In addition, contacts which contact these devices from the backside of the silicon wafer are provided so that the wafer may be held in the plasma during plasma processing and measurements taken on the test structures as the plasma processing proceeds.

The invention includes a removable test structure, which consists of the silicon test substrate with appropriate test devices that can be electrically contacted through the backside of the test substrate. The apparatus also includes a substrate chuck that includes raised probes to contact the backside of the test substrate.

As a part of the method, the process gas flow of the etching gas used for the plasma etch process may be adjusted at least once to obtain another set of signals. Similarly, the RF bias that biases the plasma may be adjusted at least once, and the wafer placement may be adjusted at least once to obtain another set of signals.

### BRIEF DESCRIPTION OF THE DRAWINGS

FIG. 1A is a top view of the test substrate of the present invention;

FIG. 1B is a side view of an exemplary test device;

FIG. 2 is a cross-section through A-A of FIG. 1A of the test substrate of the present invention;

FIGS. 3 and 4 are cross-sections through another embodiment of a test substrate of the present invention;

FIG. 5 is one embodiment of a substrate chuck of the present invention;

FIG. 6 is another embodiment of a substrate chuck of the present invention;

FIG. 7 is a diagram of a system utilizing the present invention; and

FIG. 8 is a flow chart of the process using the present invention.

### DETAILED DESCRIPTION OF THE EMBODIMENTS

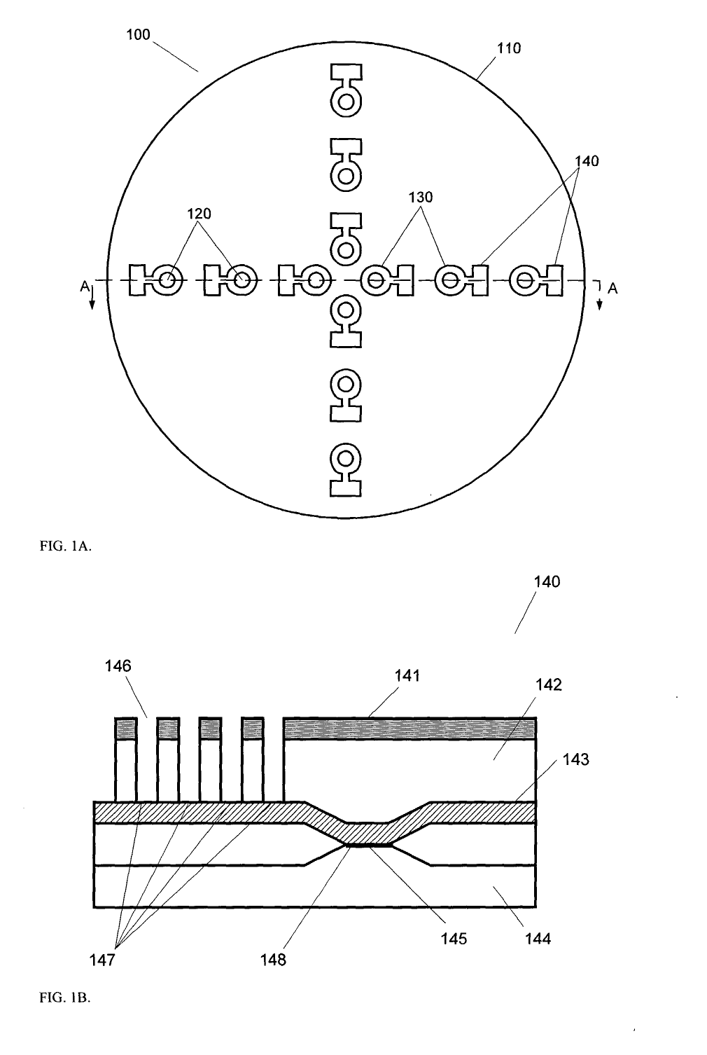

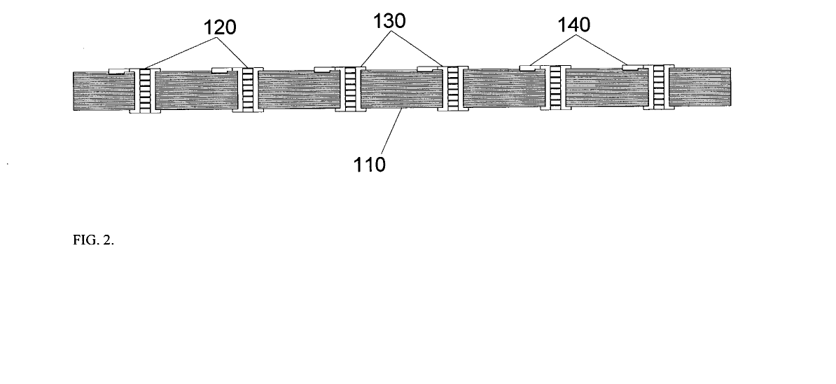

With reference to FIGS. 1A and 2, a plasma test structure 100 includes a test substrate 110, which, in this case, is a silicon wafer, that has been reduced to a thickness of around 350 microns. Formed in the silicon wafer 110 are a plurality of contact holes or channels 120 that communicate with the front side and the backside of the substrate. Contact holes 120 are lined with a conductive metal to form the metal contacts 130. Each metal contact 130 is electrically connected to a test device 140 that, in this embodiment, is formed on the surface of the silicon wafer 110. Each device 140 may be electrically connected to one or more additional contacts 130 as dictated by the number of inputs and outputs required for the specific device being used. The device 140 may include devices such as MOS transistors, BJT devices, capacitors, etc. One example of a device 140 is provided in FIG. 1B wherein a P-MOS capacitor and gate electrode is used to form an electron shading test device. The test device 140 comprises a photoresist layer 141, oxide layer 142, doped poly-silicon layer 143, P-type silicon layer 144 and oxide gate 145. Vias 146 are formed through photoresist layer 141 and oxide layer 142, wherein via antenna area 147 is exposed to plasma. The device antenna ratio is given by the ratio of the via area 147 to the gate area 148. The devices may have metal or polysilicon antennas (or antenna areas) connected to them in order to better monitor the effects of the RF power supplies. For instance, where the antennas are connected to the gates of MOS devices, the potential on the gates as the wafer is processed could be measured. In one embodiment, part of a metal or polysilicon layer is used as an antenna. The devices may also include devices to monitor plasma conditions such as an array of Langmuir probes or the like, comprising a conductor for measuring the plasma potential. In one embodiment, the probes comprise metal lined contact holes or channels of varying size and aspect ratios in the wafer 110, which extend to or from metal contact areas on the back surface of the substrate, and may extend entirely or partially to the upper surface of the substrate. In one embodiment, the contact holes 120 are 50 micrometers in diameter and have been formed by a dry etching process, and metal contacts 130 are formed of copper deposited by a through-hole plating process.

Typically, the test devices 140 are formed only partially, and require further processing in the form of an etching step. For example, a MOS device may have been partially formed by depositing a metal layer on a certain structure, depositing an oxide over the metal, and depositing a photoresist on the oxide in a patterned manner. The device requires an etching step to etch away portions of the oxide, and in accordance with the invention, the etching step can be monitored. It will, however, be appreciated that in some instances the device may not yet have been formed at all or may have been completely formed.

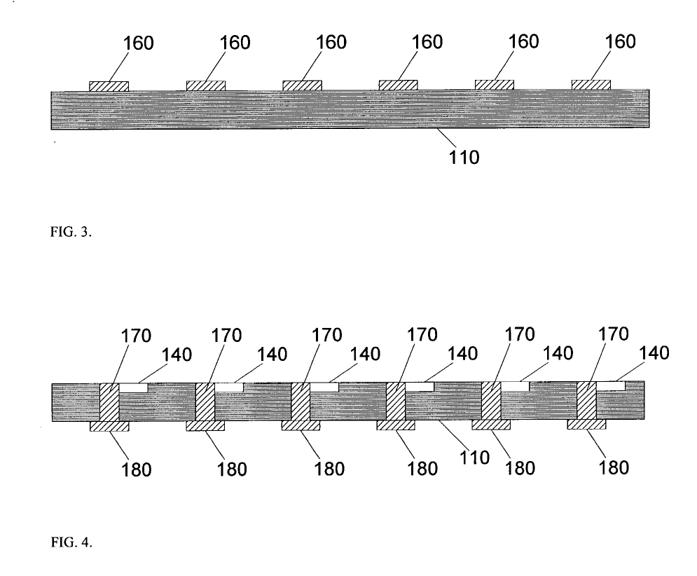

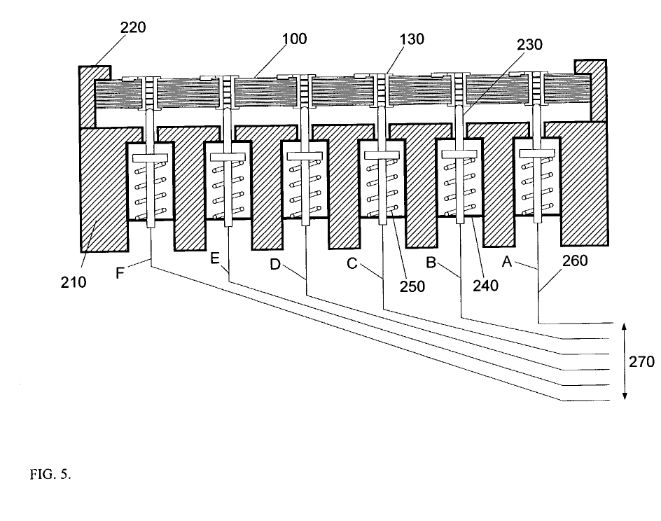

In another embodiment, shown in FIGS. 3 and 4, the contact to the backside of test wafer 110 may be realized by use of the technique of aluminum drifting. This process involves depositing dots 160 of aluminum 3 to 5 micrometers thick on an N-type silicon substrate 110 and then exposing the substrate to a temperature above the eutectic temperature of aluminum-silicon, 577° C., with a temperature gradient across the thickness of the substrate. This temperature gradient allows the molten aluminum-silicon droplets to migrate through the thickness of the substrate 110 and in a relatively short period of time, go completely through the substrate 110, so that a column of P-type material 170 is provided extending completely through the substrate, with a dot of silicon-rich aluminum 180 now on the back side of the substrate, providing a convenient contact region. The P-type column 170 is of very low resistivity, since the silicon in the region is saturated with aluminum. As in the FIG. 1A embodiment, the embodiment of FIGS. 3 and 4 will include test devices (not shown). The aluminum drifting process is preferably performed following the partial fabrication of the test devices 140, but may be performed before the fabrication of the test devices or test sensors, or after the test device fabrication.

Alternatively, the substrate 110 may be formed of a ceramic disc or an organic board, such as an epoxy-fiberglass board, rather than the silicon wafer. In either case, the ceramic disc or organic board may optionally be of multi-level construction. Likewise, devices 140 may be replaced with discretely wired test devices such as chips bonded onto the ceramic disk or board.

Illustrated in FIG. 5 is a substrate chuck 210, in which substrate clamps 220 have clamped test structure 100. The metal contacts 130 are aligned with metal pushpins 230, which have slides inside insulating sleeves 240. The metal pushpins 230 are forced upwards by springs 250 where they physically contact the metal contacts 130, forming electrical connections. Each metal pushpin 230 is electrically connected to a conductor 260. The conductors 260 are bundled to form a shielded cable 270 that is routed out of the process chamber through a shielded connector (not shown) to appropriate test instrumentation (not shown). Desirably, substrate chuck 210 comprises at least one channel for substrate chuck temperature control (i.e. cooling) and at least one channel for substrate temperature control (i.e. cooling) during plasma processing.

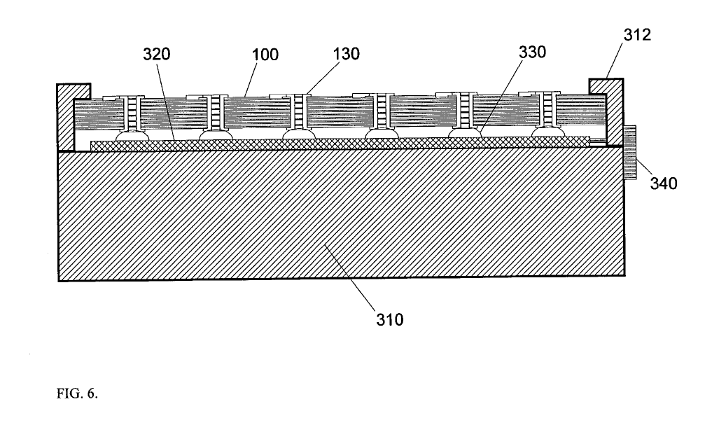

Another embodiment of the substrate chuck of the instant invention, illustrated in FIG. 6, is the substrate chuck 310, in which substrate clamps 312 have clamped a test structure 100. The test structure 100 is aligned with a circuit board 320 that has contacts 330. Contacts 330 physically contact metal contacts 130 on the test wafer of the structure 110, forming electrical connections. The contacts 330 are electrically coupled to a connector 340 that is connected to the appropriate test instrumentation (not shown).

In one embodiment, the circuit board 320 is a multi-layered ceramic, and the contacts 330 are metal balls or bumps such as lead-tin balls, copper balls, gold bumps or aluminum bumps. In a second example, the circuit board 320 is an organic board, such as epoxy-fiberglass, and the contacts 330 are metal balls or bumps such as lead-tin balls, copper balls, gold bumps or aluminum bumps. The connector 340 can, for example, be an RS-232 connector, a cable edge connector or an optical fiber port.

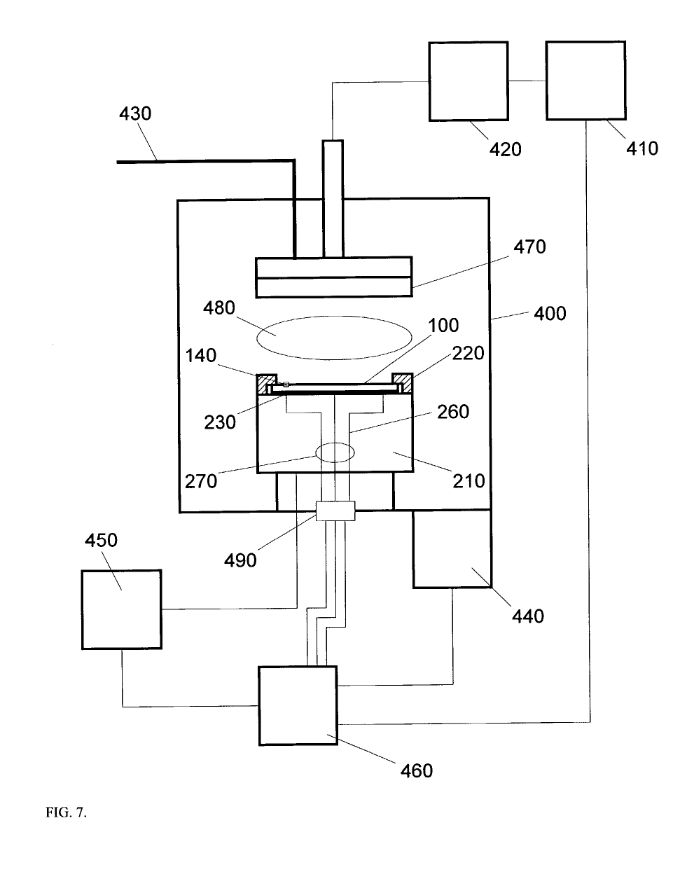

FIG. 7 shows the system of the present invention. Chamber 400 is a plasma processing chamber, fitted with a vacuum pump 440, and an RF power source 410 and matching network 420 that matches the output impedance of the power source to the impedance of the load (in this case the plasma). The power source 410 with its matching network 420 feeds RF energy to the upper electrode assembly 470 which is also equipped with a process gas inlet system 430. A processing plasma 480 is generated by the action of the RF energy supplied by the RF power supply 410 and the matching network 420 on the process gas supplied through process gas inlet system 430. Bias to the plasma is provided by RF bias power supply 450.

The test structure 100 is held in substrate chuck 210 by wafer clamps 220. Pushpins 230 contact the backside contacts 130/180 (FIGS. 2/4) of the test structure 100. Signals from the test devices 140 on the test substrate 110 are fed out of the substrate chuck by the conductors 260 which are formed into the cable 270, and out of the chamber by the vacuum-tight feed-through connector 490. In one embodiment, fiber optic cables and optical couplers are used. The data is then communicated to a computer 460. Computer 460 also communicates with the RF power sources 410 and 450. The computer 460 is also provided with a data-out path, so that the data generated by the test structure 100 may be gathered and interpreted while the test structure 100 is being processed. The specific data gathered and their interpretation depends on the specific devices 140 fabricated in wafer 110. For example, if the test devices 140 are MOS transistors, the data could consist of measurements of source-drain current (Ids), for example, or the gate oxide leakage current (Ig). It will be appreciated that signals may be generated in the test devices by virtue of the plasma. However, the invention also contemplates providing power to the test devices to monitor the effect on the outputs of the devices as a result of the plasma. As is well known to those skilled in the art of plasma processing, the charging of devices is dependent on several properties of the plasma as well as the substrate. These parameters can be, for example, the plasma density, plasma uniformity, feature size and aspect ratio, feature geometry, feature pattern, etc. Moreover, the charging of devices arises generally from the difference in mobility of the ions relative to the electrons.

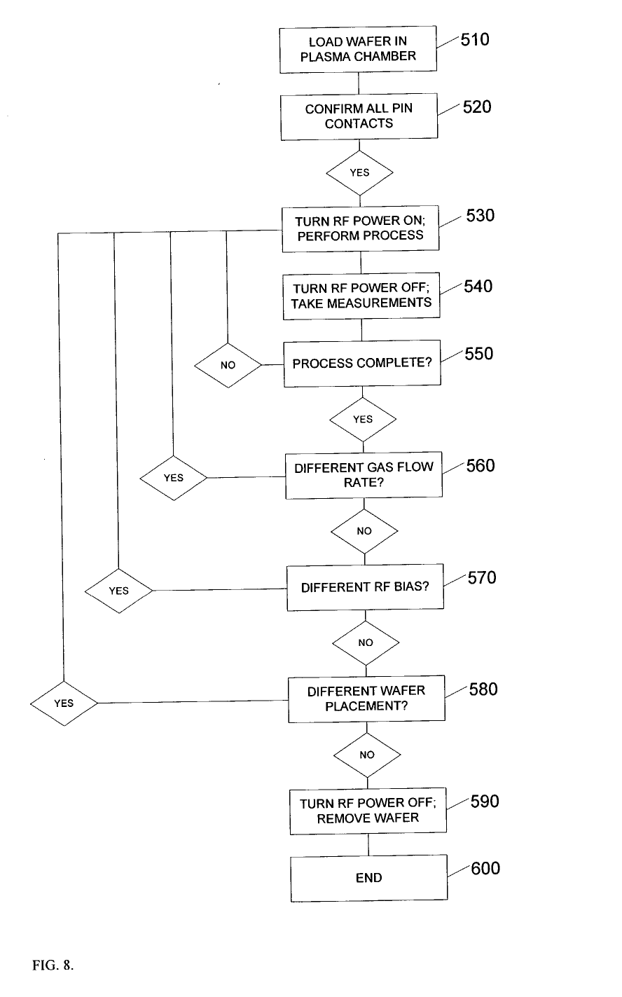

FIG. 8 is a flow chart of a method for the use of the test structure 100. The process begins by loading test structure 100 into plasma process chamber 400 and onto substrate chuck 210 as shown in step 510. In step 520, contact to all of the contacts 130 or 180 of the structure 100 by metal pushpins 230 is checked and confirmed. If good contact is not obtained, the test structure 100 should be removed from the chamber and reloaded to obtain proper contact. If good contact is achieved, the process proceeds to step 530 in which the RF power is applied and the plasma process is begun. If the signals obtained from the test devices 140 are very weak, such that even with the shielding achieved with the substrate chuck 210 and cable 270 the RF pick-up from the RF power supplies swamps out the signal, in step 540 the RF power is turned off for a period of time just long enough to take the measurements, as indicated by step 540. This time should be as short as possible, on the order of microseconds to a few milliseconds, to ensure that a minimum of change in the plasma conditions takes place while the measurements are taken. When the process is complete (step 550), the operator has the decision as to whether or not to adjust the gas flow rate in step 560, utilize a different RF bias power in step 570 and/or utilize a different wafer placement in step 580. Following this series of decisions, the RF power is turned off in step 590 and the structure 100 removed from the plasma process chamber 400 and the flow chart ends in step 600.

While the present invention has been particularly shown and described with reference to some specific embodiments thereof, it will be understood by those skilled in the art that various changes in form and detail may be made therein without departing from the spirit and scope of the invention.

What is claimed is:

1. A method of monitoring the effect of a plasma in a plasma etch process on devices that are exposed to the plasma in a plasma process chamber, comprising:
providing a substrate having at least one test device;
providing at least one contact that is structured and arranged to contact the at least one test device from the back side of the substrate; and
measuring signals received from the at least one contact, while the substrate is in the chamber.

2. The method of claim 1, wherein the at least one test device is a partially manufactured device.

3. The method of claim 2, wherein the at least one test device includes at least one layer that is etched by the plasma.

4. The method of claim 2; wherein the at least one test device is a MOS device.

5. The method of claim 1, wherein the at least one test device is a Langmuir probe-like device.

6. The method of claim 5, wherein the at least one contact comprises a metal or metal rich conductor extending from the back surface of the substrate at least partially to the top surface of the substrate.

7. The method of claim 6, wherein the test device is a metal-lined channel.

8. The method of claim 1, further comprising adjusting the process gas flow of the etching gas used for the plasma etch process at least once to obtain another set of signals.

9. The method of claim 1, further comprising adjusting a RF bias that biases the plasma at least once to obtain another set of signals.

10. The method of claim 1, further comprising adjusting the substrate placement at least once to obtain another set of signals.

11. The method of claim 1, wherein the substrate comprises at least one of silicon wafer, ceramic disk, and substrate made of an organic material.

12. The method of claim 11, wherein the substrate is made of an organic material and comprises an epoxy-fiberglass board.

13. The method of claim 1, wherein the at least one contact comprises metal-lined channels.

14. The method of claim 1, wherein the providing of the at least one contact comprises depositing a metal dot on the substrate, exposing the substrate to a temperature above the eutectic temperature of the metal-substrate material, with a temperature gradient across the thickness of the substrate, and allowing the metal-substrate material to migrate through the substrate to form a column of P-type material.

15. The method of claim 14, wherein the metal is aluminum.

16. The method of claim 1, further comprising providing a substrate chuck with probes for contacting the at least one contact.

17. The method of claim 16, wherein the probes comprise pins slidably mounted in the chuck.

18. The method of claim 17, wherein the probes are spring biased.

19. The method of claim 1, further comprising providing a substrate chuck and a circuit board with metal bumps formed on the circuit board, wherein the bumps contact the at least one contact when the substrate is mounted on the chuck.

20. The method of claim 19, wherein the metal bumps are lead, tin, gold, or copper bumps.

21. The method of claim 1, further comprising providing each test device with at least one contact.

22. The method of claim 21, wherein the contact for each test device comprises a number of inputs and outputs to the device.

23. The method of claim 1, further comprising providing an antenna for at least one test device.

24. The method of claim 1, further comprising supplying power to the at least one test device.

25. The method of claim 1, further comprising connecting at least two of the test devices to each other.

26. A method of monitoring a plasma in a plasma process chamber, comprising:
placing a test substrate having at least one test device in the chamber;
providing at least one contact that is structured and arranged to contact the at least one test device from the back side of the substrate, and measuring signals received from the at least one contact, while the test substrate is in the chamber.

27. The method of claim 26, wherein the measuring is a continuous measuring or measurements taken at intervals.

28. A method of monitoring the effect of a plasma on a semiconductor device in a plasma process chamber, comprising:
placing a test substrate with at least one semiconductor device, in the chamber;
contacting the at least one semiconductor device from the back side of the substrate; and
measuring signals received from the at least one semiconductor device due to the plasma.

29. An apparatus for monitoring the effect of a plasma in a plasma etch process on devices that are exposed to the plasma in a plasma process chamber, comprising:
a substrate having at least one test device on one surface; and
at least one contact that is structured and arranged to contact the at least one test device from the other surface of the substrate opposite the one surface.

30. The apparatus of claim 29, wherein the at least one test device is a partially manufactured device.

31. The apparatus of claim 30, wherein the at least one test device includes at least one layer that is etched by the plasma.

32. The apparatus of claim 30, wherein the at least one test device is a MOS device.

33. The apparatus of claim 29, wherein the at least one test device is a Langmuir probe-like device.

34. The apparatus of claim 33, wherein the at least one contact comprises a metal or metal rich conductor extending from the back surface of the substrate at least partially to the top surface of the substrate.

35. The apparatus of claim 34, wherein the test device is a metal-lined channel.

36. The apparatus of claim 29, further comprising means for adjusting a RF bias that biases the plasma, the biasing means including means for changing the adjustment at least once during a process to obtain another set of signals.

37. The apparatus of claim 29, wherein the substrate comprises at least one of silicon wafer, ceramic disk, and substrate made of an organic material.

38. The apparatus of claim 37, wherein the substrate is made of an organic material and comprises an epoxy-fiberglass board.

39. The apparatus of claim 29, wherein the at least one contact comprises metal-lined channels.

40. The apparatus of claim 29, wherein the at least one contact comprises a column of P-type material extending through the substrate, the column having a metal diffused through the substrate.

41. The apparatus of claim 40, wherein the metal is aluminum.

42. The apparatus of claim 29, further comprising a substrate chuck with probes for contacting the at least one contact.

43. The apparatus of claim 42, wherein the probes comprise pins slidably mounted in the chuck.

44. The apparatus of claim 43, wherein the probes are spring biased.

45. The apparatus of claim 29, further comprising a substrate chuck and a circuit board with metal bumps formed on the circuit board, wherein the bumps contact the at least one contact when the substrate is mounted on the chuck.

46. The apparatus of claim 45, wherein the metal bumps are lead, tin, gold, or copper bumps.

47. The apparatus of claim 29, further comprising at least one contact for each test device.

48. The apparatus of claim 47, wherein the contact for each test device comprises a number of inputs and outputs to the device.

49. The apparatus of claim 29, further comprising an antenna attached to the at least one test device.

50. The apparatus of claim 29, further comprising a conductor supplying power to the at least one contact of the at least one test device.

51. The apparatus of claim 29, further comprising a second test device coupled to the first mentioned test device.

52. An apparatus of monitoring a plasma in a plasma process chamber, comprising:
a substrate having at least one test device on one surface; and
at least one contact that is structured and arranged to contact the at least one test device from the other surface of the substrate opposite the one surface.

53. A apparatus of monitoring the effect of a plasma on a semiconductor device in a plasma process chamber, comprising:
a substrate having at least one semiconductor test device on one surface; and
at least one contact that is structured and arranged to contact the at least one semiconductor test device from the other surface of the substrate opposite the one surface.
